(19) United States
(12) Patent Application Publication
(10) Pub. No.: US 2024/0222432 A1
(43) Pub. Date: Jul. 4, 2024

(54) SEMICONDUCTOR DEVICE INCLUDING TWO-DIMENSIONAL (2D) MATERIAL

(71) Applicant: Samsung Electronics Co., Ltd., Suwon-si (KR)

(72) Inventors: Joungeun YOO, Suwon-si (KR); Duseop YOON, Suwon-si (KR); Kyung-Eun BYUN, Suwon-si (KR); Minsu SEOL, Suwon-si (KR)

(73) Assignee: Samsung Electronics Co., Ltd., Suwon-si (KR)

(21) Appl. No.: 18/401,855

(22) Filed: Jan. 2, 2024

(30) Foreign Application Priority Data
Jan. 3, 2023 (KR) 10-2023-0000920

(51) Int. Cl. H01L 29/06; H01L 29/417; H01L 29/786

(52) U.S. Cl. CPC H01L 29/0673; H01L 29/41725; H01L 29/78696

(57) ABSTRACT

A semiconductor device may include a two-dimensional (2D) material layer having semiconductor characteristics, and a source electrode, a drain electrode, and a gate electrode spaced apart from one another on the 2D material layer. At least one of the source electrode and the drain electrode may be in contact with the 2D material layer and may include an alloy layer that may be amorphous.

### CROSS-REFERENCE TO RELATED APPLICATION

This application is based on and claims priority under 35 U.S.C. § 119 to Korean Patent Application No. 10-2023-0000920, filed on Jan. 3, 2023, in the Korean Intellectual Property Office, the disclosure of which is incorporated by reference herein in its entirety.

### BACKGROUND

### 1. Field

The present disclosure relates to a thin-film structure including a two-dimensional (2D) material, a semiconductor device, and an apparatus including the semiconductor device.

### 2. Description of the Related Art

While the degree of integration may be improved due to continuous scaling of semiconductor devices, a performance limitation for the use of three-dimensional (3D) bulk materials is gradually being revealed, and research on the development of two-dimensional (2D) materials is continuously reported to overcome this limitation. Unlike 3D bulk materials, 2D materials can be very promising as next-generation semiconductor materials because they are stable and have excellent performance even when they have small thicknesses.

In a semiconductor device using an existing 3D bulk material as a channel, when the thickness of the channel decreases, mobility decreases and the distribution of threshold voltages increases. In addition, when the length of the channel decreases, a performance degradation due to a short channel effect becomes severe.

However, it is confirmed that these problems are addressed due to use of a 2D material layer, and thus, the development of a 2D is in the spotlight as a method of overcoming a semiconductor device scaling limitation.

### SUMMARY

Provided are a thin-film structure capable of reducing contact resistance with a two-dimensional (2D) material layer having semiconductor characteristics, a semiconductor device, and an electronic apparatus including the semiconductor device.

Additional aspects will be set forth in part in the description which follows and, in part, will be apparent from the description, or may be learned by practice of the presented embodiments of the disclosure.

According to an embodiment, a semiconductor device may include a 2D material layer having semiconductor characteristics, and a source electrode, a drain electrode, and a gate electrode spaced apart from one another on the 2D material layer. At least one of the source electrode and the drain electrode may be in contact with the 2D material layer and may include an alloy layer that is amorphous.

In some embodiments, the alloy layer may have semimetal characteristics.

In some embodiments, the alloy layer may include a first metal and a second metal that may be different from each other.

In some embodiments, the first metal may be one of aluminum (Al), gallium (Ga), indium (In), titanium (Ti), and tin (Sn).

In some embodiments, the second metal may be one of samarium (Sm), europium (Eu), lanthanum (La), cerium (Ce), and lutetium (Lu).

In some embodiments, a content of the first metal in the alloy layer may be greater than a content of the second metal in the alloy layer.

In some embodiments, a ratio of the content of the first metal to the content of the second metal may be about 8 to about 10.

In some embodiments, the alloy layer may further include a chalcogen element.

In some embodiments, the chalcogen element may further include at least one of selenium (Se), tellurium (Te), polonium (Po), and livermorium (Lv).

In some embodiments, the content of the chalcogen element in the alloy layer may be 50 at % or less.

In some embodiments, the content of the chalcogen element in the alloy layer may be 20 at % or less.

In some embodiments, a melting point of the alloy layer may be 800° C. or more.

In some embodiments, the 2D material layer may include transition metal dichalcogenide (TMD).

In some embodiments, the TMD may include a metal element and a chalcogen element. The metal element may include one of Mo, W, Nb, V, Ta, Ti, Zr, Hf, Tc, Re, Cu, Ga, In, Sn, Ge, and Pb. The chalcogen element may include one of S, Se, and Te.

In some embodiments, a thickness of the 2D material layer may be 5 nm or less.

In some embodiments, at least one of the source electrode and the drain electrode may further include a metal layer on the alloy layer.

In some embodiments, at least one of the source electrode and the drain electrode may further include a plurality of islands spaced apart from one another between the 2D material layer and the alloy layer.

In some embodiments, the semiconductor device may further include an alignment adjustment layer on a different region of the 2D material layer than a region of the 2D material layer in which the source electrode and the drain electrode are disposed. The alignment adjustment layer may be configured to adjust energy-band alignment between the 2D material layer and at least one of the source electrode and the drain electrode.

In some embodiments, the alignment adjustment layer may overlap at least one of the source electrode and the drain electrode in a thickness direction of the 2D material layer.

In some embodiments, the alignment adjustment layer may include a 2D material having insulating properties.

### BRIEF DESCRIPTION OF THE DRAWINGS

The above and other aspects, features, and advantages of certain embodiments of inventive concepts will be more apparent from the following description taken in conjunction with the accompanying drawings, in which:

FIG. 1 is a diagram of a thin film structure according to an embodiment;

FIG. 2 is a graph showing a result of simulating a melting point of an alloy containing a plurality of different metals according to an embodiment.

FIG. 3 is a graph showing a result of simulating a density of states (DOS) according to the content of tellurium (Te) in an alloy of AlSmTe according to an embodiment;

FIG. 4 is a graph showing a result of simulating the melting point of an alloy containing aluminum (Al) and tellurium (Te) according to an embodiment;

FIG. 5 is a cross-sectional view of a semiconductor device including a 2D material layer according to an embodiment;

FIG. 6 is a cross-sectional view of a semiconductor device having a lateral heterojunction structure, according to an embodiment;

FIG. 7 is a cross-sectional view of a semiconductor device having a vertical and lateral heterojunction structure, according to an embodiment;

FIG. 8 is a cross-sectional view of a semiconductor device including a metal layer, according to an embodiment;

FIG. 9 is a cross-sectional view of a semiconductor device including a plurality of islands, according to an embodiment;

FIG. 10 is a cross-sectional view of a semiconductor device including an alignment adjustment layer, according to an embodiment;

FIG. 11 shows a memory device including a data storage element connected to a switching device, according to an embodiment;

FIG. 12 is a diagram of a memory apparatus in which a plurality of memory devices of FIG. 11 are stacked vertically;

FIG. 13 is a block diagram for schematically explaining an electronic apparatus including a memory apparatus, according to an embodiment;

FIG. 14 is a block diagram schematically showing a memory system including a volatile memory apparatus according to an embodiment;

FIG. 15 is a schematic diagram of a neuromorphic apparatus including a memory apparatus according to an embodiment; and

FIG. 16 is a circuit diagram of an inverter according to an embodiment.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items.

Embodiments will now be described more fully with reference to the accompanying drawings. Like reference numerals in the drawings denote like elements, and, in the drawings, the sizes of elements may be exaggerated for clarity and for convenience of explanation. In this regard, the present embodiments may have different forms and should not be construed as being limited to the descriptions set forth herein.

When a layer is referred to as being ““on” another layer or substrate, it can be directly on/below/on the left side of/on the right side of the other layer or substrate, or intervening layers may also be present. An expression used in the singular encompasses the expression of the plural, unless it has a clearly different meaning in the context. The terms “comprises” and/or “comprising” or “includes” and/or “including” when used in this specification, specify the presence of stated elements, but do not preclude the presence or addition of one or more other elements.

The use of the terms “a” and “an” and “the” and similar referents are to be construed to cover both the singular and the plural. The operations that constitute a method described herein can be performed in any suitable order unless otherwise indicated herein or otherwise clearly contradicted by context, but embodiments are not limited to the stated order.

The terms “unit”, “-er (-or)”, and “module” when used in this specification refers to a unit in which at least one function or operation is performed, and may be implemented as hardware, software, or a combination of hardware and software.

The connecting lines, or connectors shown in the various figures presented are intended to represent example functional relationships and/or physical or logical couplings between the various elements. It should be noted that many alternative or additional functional relationships, physical connections or logical connections may be present in a practical device.

Expressions such as “at least one of,” when preceding a list of elements, modify the entire list of elements and do not modify the individual elements of the list. For example, an expression such as “at least one of A, B, and C” or “at least one selected from the group consisting of A, B, and C” may be interpreted as only A, only B, only C, or combinations of two or more of A, B, and C, such as ABC, AB, BC, and AC.

When “about” or “substantially” is used in relation to a numerical value, the related numerical value may be interpreted as including manufacturing or operating deviations (e.g., ±10%) around a stated numerical value. Furthermore, when the terms “generally” and “substantially” are used in relation to geometric shapes, this may intend that geometrical precision is not required and latitude for shapes is within the scope of the present embodiment. Moreover, regardless of whether a numerical value or a shape is restricted to “about” or “substantially”, the numerical value and the shape may be interpreted as including manufacturing or operating deviations (e.g., +10%) around a stated numerical value.

While such terms as “first”, “second”, etc., may be used to describe various components, such components should not be limited to the above terms. The above terms are used only to distinguish one component from another.

The use of any and all examples, or example language provided herein, is intended merely to better illuminate the technical spirit and does not pose a limitation on the scope of the present disclosure unless otherwise claimed.

Example embodiments of the disclosure will now be described more fully with reference to the accompanying drawings.

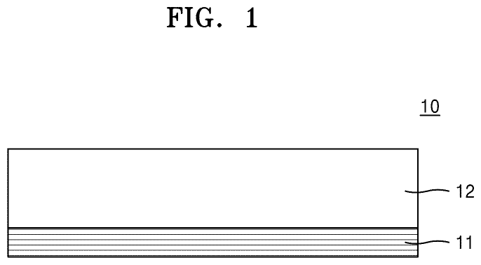

FIG. 1 is a diagram of a thin film structure 10 according to an embodiment. Referring to FIG. 1, the thin film structure 10 may include a two-dimensional (2D) material layer 11 having a semiconductor property, and an amorphous alloy layer 12 in contact with the 2D material layer 11.

The 2D material denotes a material having a 2D crystallization structure. The 2D material may have a monolayer or multilayer structure. Each layer in the 2D material may have a thickness of an atomic level. The 2D material may include, for example, at least one of graphene, black phosphorous, and transition metal dichalcogenide (TMD).

TMD may include, for example, one transition metal from among Mo, W, Nb, V, Ta, Ti, Zr, Hf, Tc, and Re, and one chalcogen element from among S, Se, and Te. TMD may be expressed as, for example, MX₂, where M denotes a transition metal and X denotes a chalcogen element. For example, M may be Mo, W, Nb, V, Ta, Ti, Zr, Hf, Tc, or Re, and X may be S, Se, or Te. Therefore, TMD may include, for example, MoS₂, MoSe₂, MoTe₂, WS₂, WSe₂, WTe₂, ZrS₂, ZrSe₂, HfS₂, HfSe₂, NbSe₂, ReSe₂, etc. Alternatively, TMD may not be expressed as MX₂. In this case, for example, TMD may include CuS that is a compound of Cu, which is a transition metal, and S, which is a chalcogen element. TMD may be a chalcogenide material including a non-transition metal. The non-transition metal may include, for example, Ga, In, Sn, Ge, Pb, etc. In this case, TMD may include a compound of a non-transition metal, such as Ga, In, Sn, Ge, or Pb, and a chalcogen element, such as S, Se, or Te. For example, TMD may include SnSe₂, GaS, GaSe, GaTe, GeSe, In₂Se₃, InSnS₂, etc.

As described above, TMD may include one metal element from Mo, W, Nb, V, Ta, Ti, Zr, Hf, Tc, Re, Cu, Ga, In, Sn, Ge, and Pb and one chalcogenide element from S, Se, and Te. However, the aforementioned materials are only examples, and various other materials may be used as TMD materials.

The 2D material layer 11 may have a thickness of about 5 nm or less or about 3 nm or less, which is very small. For example, the 2D material layer 11 may have a single layer. Alternatively, the 2D material layer 11 may have one to ten layers or one to five layers. When applying the 2D material layer 11 to the thin film structure 10, scaling of the thin film structure 10 may be reduced.

In order for carriers to move through the 2D material layer 11, a contact layer for applying the carriers to the 2D material layer 11 is needed. When the contact layer for applying the carriers is a metal layer, high contact resistance is generated between the 2D material layer and the metal layer. One of the causes of high contact resistance is that a metal induced gap state (MIGS) is generated by an interaction between a metal and a 2D material.

In order to reduce the MIGS, the thin film structure 10 according to an embodiment may include the amorphous alloy layer 12 in contact with the 2D material layer 11. An alloy, which is a material made by adding another metal or a non-metal element to a metal, may have different properties from those of the metal included in the alloy. When the alloy layer 12 has a crystalline phase, electrical conductivity is increased, and thus, the alloy layer 12 according to an embodiment may be in an amorphous phase. The alloy layer 12 according to an embodiment may have semimetal properties.

A semimetal material may be used to form the contact layer of the 2D material layer 11. The semimetal material may reduce an MIGS, but has poor thermal stability. Thus, a semimetal material is difficult to apply to a production process of a semiconductor device 100. For example, a melting point of bismuth (Bi) having metalloid properties is as low as about 271° C., which makes it difficult to apply bismuth to a process.

The alloy layer 12 according to an embodiment has excellent thermal stability with a melting point of about 700° C. or more or about 800° C. or more while having semi-metal characteristics with a low density of states (DOS).

Because the alloy layer 12 according to an embodiment has a semimetal electronic structure, an MIGS may be reduced when the alloy layer 12 is used as the contact layer of the 2D material layer 11. When the alloy layer 12 is used as the contact layer of the 2D material layer 11, contact resistance may be effectively reduced.

The alloy layer 12 according to an embodiment may include a first metal and a second metal that are different from each other. The first metal may be one of aluminum (Al), gallium (Ga), indium (In), titanium (Ti), and tin (Sn), and the second metal may be one of samarium (Sm), europium (Eu), lanthanum (La), cerium (Ce), and lutetium (Lu).

The content of the first metal in the alloy layer 12 may be greater than the content of the second metal. The ratio of the content of the first metal to the content of the second metal may be about 8 to about 10. For example, the ratio of the content of the first metal to the content of the second metal may be about 9.

A melting point of the alloy layer 12 may vary depending on a composition of the first metal and the second metal included in the alloy layer 12. The alloy layer 12 according to an embodiment may have a much higher melting point than semimetal. The melting point of the alloy layer 12 according to an embodiment may be about 700° C. or more, about 800° C. or more, about 900° C. or more, or about 1000° C. or more.

The alloy layer 12 according to an embodiment may further include a chalcogen element. For example, the alloy layer 12 may further include at least one of selenium (Se), tellurium (Te), and polonium (Po). Because the chalcogen element has a greater energy band gap than metal, the chalcogen element may strengthen the semimetal characteristics of the alloy layer 12. The energy band gap of the chalcogen element included in the alloy layer 12 may be about 0.5 eV to about 2 eV.

When the chalcogen element is included in the alloy layer 12, the semimetal characteristics may be strengthened, but, when the content of the chalcogen element increases too much, the melting point of the alloy layer 12 may be lowered. Thus, the content of the chalcogen element in the alloy layer 12 may be more than 0 at %, 10 at % or more, 20 at % or more, 30 at % or more, 45 at % or less, or 50 at % or less.

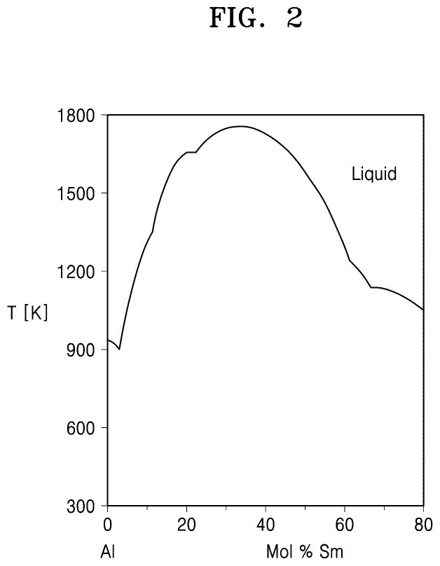

FIG. 2 is a graph showing a result of simulating the melting point of an alloy containing a plurality of different metals according to an embodiment. As shown in FIG. 2, it may be seen that an alloy including aluminum (Al) and samarium (Sm) has a higher melting point than a material formed of only aluminum. It may also be seen that the melting point may vary depending on the composition of aluminum (Al) and samarium (Sm).

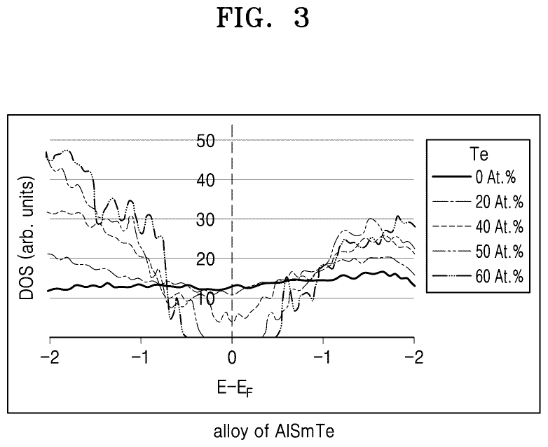

FIG. 3 is a graph showing a result of simulating a DOS according to the content of Te in an alloy of AlSmTe according to an embodiment. It may be seen that, when the alloy does not include Te, there is almost no change in the DOS in a negative direction or the DOS in a positive direction. However, it may be seen that, when the alloy includes Te, the DOS in the negative direction or the DOS in the positive direction increases. Thus, it may be seen that the semimetal characteristics of the alloy may be adjusted by controlling an amount of Te.

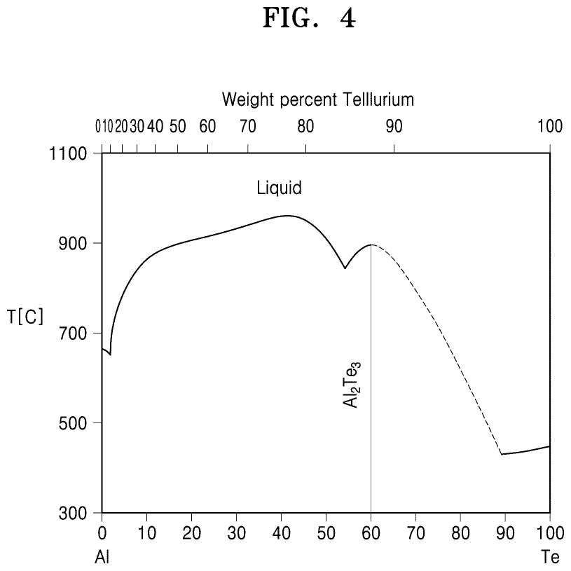

FIG. 4 is a graph showing a result of simulating the melting point of an alloy containing aluminum (AI) and tellurium (Te) according to an embodiment. As shown in FIG. 4, it may be seen that an alloy including aluminum (Al) and tellurium (Te) may vary depending on a combination of the aluminum (Al) and the tellurium (Te). An alloy containing a small amount of tellurium (Te) has a higher melting point than aluminum (Al). However, when the content of tellurium (Te) excessively increases, the melting point of the alloy may be lowered. Thus, the content of the tellurium (Te) included in the alloy layer 12 according to an embodiment may be about 50 at % or less or about 45 at % or less.

The thin film structure 10 according to an embodiment may be one component of the semiconductor device 100. The semiconductor device 100 may include, for example, a field effect transistor (FET). In the FET, the 2D material layer 11 may be a channel layer 110, and the alloy layer 12 may be a drain electrode 130 or a source electrode 120.

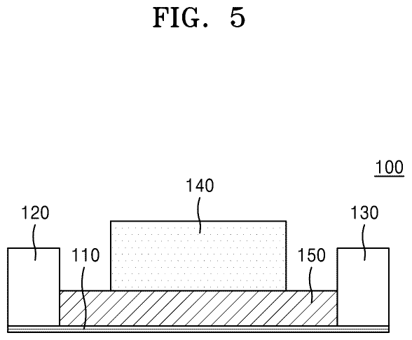

FIG. 5 is a cross-sectional view of a semiconductor device 100 including a 2D material layer, according to an embodiment. Referring to FIG. 5, the semiconductor device 100 may include the channel layer 110, the source electrode 120 and the drain electrode 130 disposed on the channel layer 110 and spaced apart from each other, a gate electrode 140 spaced apart from the channel layer 110, and a gate insulating layer 150 disposed between the channel layer 110 and the gate electrode 140.

The channel layer 110 may be provided in the form of an ultra-thin film. The channel layer 110 may be the 2D material layer 11 described above. The channel layer 110 may be disposed on a substrate (not shown). The substrate may include insulating substrates made of various materials. The substrate may further include, for example, an impurity region by doping, an electronic device such as a transistor, or a peripheral circuit for selecting and controlling memory cells that store data.

The source electrode 120 and the drain electrode 130 may be disposed on the channel layer 110 and be spaced apart from each other. The source electrode 120 and the drain electrode 130 may be disposed on the same surface of the channel layer 110. At least one of the source electrode 120 and the drain electrode 130 may include the alloy layer 12 described above. The source electrode 120 and the drain electrode 130 may be provided to contact upper surfaces of both side portions of the channel layer 110. For example, the source electrode 120 and the drain electrode 130 may be disposed to overlap the channel layer 110 in a thickness direction of the channel layer 110. A planar contact may be formed between the source electrode 120 and the channel layer 110 and between the drain electrode 130 and the channel layer 110. For example, a planar contact may be formed between the alloy layer and the channel layer 110. A contact of a vertical heterojunction structure may be formed between the 2D material layer of the channel layer 110 and the alloy layer of the source electrode 120 or the drain electrode 130.

The gate electrode 140 may be disposed on the channel layer 110 and between the source electrode 120 and the drain electrode 130. The gate electrode 140, the source electrode 120, and the drain electrode 130 may be disposed on the same surface of the channel layer 110.

According to an embodiment, the gate electrode 140 may include an electrically conductive material.

The gate electrode 140 may include a metal, a conductive nitride, or a conductive oxide. The metal may include, for example, at least one of Au, Ti, W, Mo, Pt, and Ni. The conductive nitride may include, for example, TIN, TaN, and WN, and the conductive oxide may include, for example, indium tin oxide (ITO) and indium zinc oxide (IZO). However, this is only an example.

The gate insulating layer 150 may be disposed between the channel layer 110 and the gate electrode 140 to electrically disconnect (e.g., insulate) the channel layer 110 from the gate electrode 140. The gate insulating layer 150 may include, for example, a silicon nitride, but embodiments are not limited thereto. Alternatively, the gate insulating layer 150 may include a ferroelectric material. For example, the ferroelectric material may include at least one of an oxide ferroelectric material, a polymer ferroelectric material, a fluoride ferroelectric material such as BMF (BaMgF₄), and/or a ferroelectric material semiconductor.

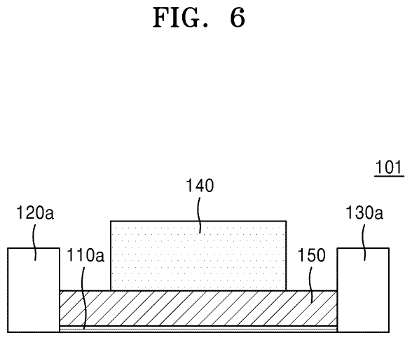

FIG. 6 is a cross-sectional view of a semiconductor device 101 having a lateral heterojunction structure, according to an embodiment. Differences from the above-described embodiment are mainly described.

A channel layer 110a may be the 2D material layer described above with reference to FIG. 1. The 2D material layer may include, for example, TMD, black phosphorus, or graphene. However, this is only an example.

The 2D material layer constituting the channel layer 110a may have a single-layer or multi-layer structure. For example, the 2D material layer 11 may include 1 to 10 layers (e.g., 1 to 5 layers). However, embodiments are not limited thereto. The channel layer 110a may further include a dopant, such as a p-type dopant or an n-type dopant. The gate insulating layer 150 is provided at the center of the channel layer 110a, and the gate electrode 140 is provided on the gate insulating layer 150.

A source electrode 120a and a drain electrode 130a may be disposed on both sides of the channel layer 110a including the 2D material layer, respectively. At least one of the source electrode 120a and the drain electrode 130a may include the alloy layer 12 described above with reference to FIG. 1. For example, each of the source electrode 120a and the drain electrode 130a may be an amorphous alloy layer having semiconductor characteristics.

The source electrode 120a and the drain electrode 130a may be provided to contact lateral surfaces (source/drain contact regions) of both side portions of the channel layer 110. In a thickness direction of the channel layer 110a, the source electrode 120a and the channel layer 110a, and the drain electrode 130a and the channel layer 110a may not overlap each other. Accordingly, an edge contact may be formed between the source electrode 120a and the channel layer 110a, and an edge contact may also be formed between the drain electrode 130a and the channel layer 110a. For example, a 2D material layer that is the channel layer 110a, and an alloy layer that is the source electrode 120 or the drain electrode 130 may form a contact of a lateral heterojunction structure.

The source electrode 120a and the drain electrode 130a, which are alloy layers, are provided on both sides of the channel layer 110a, which is a 2D material layer, respectively, to be in contact with the both sides of the channel layer 110a, so that contact resistance between the channel layer 110a and the source electrode 120a and the channel layer 110a and the drain electrode 130a may be reduced.

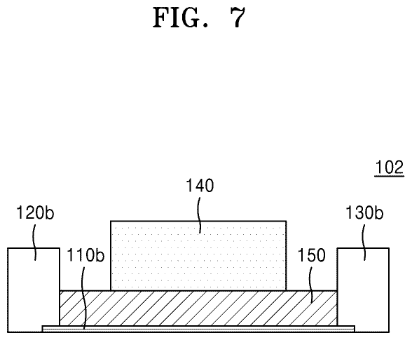

FIG. 7 is a cross-sectional view of a semiconductor device 102 having a vertical and lateral heterojunction structure, according to an embodiment. Differences from the embodiments described above are mainly described.

Referring to FIG. 7, a channel layer 110b including the 2D material layer of FIG. 1 is provided on a substrate. The 2D material layer may include, for example, TMD, black phosphorus, or graphene. However, this is only an example.

The 2D material layer included in the channel layer 110b may have a single-layer or multi-layer structure. The 2D material layer may include 1 to 10 layers (e.g., 1 to 5 layers). The channel layer 110b may further include a desired and/or alternatively predetermined dopant. The gate insulating layer 150 is provided at the center of the channel layer 110b, and the gate electrode 140 is provided on the gate insulating layer 150.

A source electrode 120b and a drain electrode 130b are provided on both sides of the channel layer 110b including the 2D material layer, respectively. The source electrode 120b and the drain electrode 130b may include the amorphous alloy layer 12.

The source electrode 120b and the drain electrode 130b may be provided to contact upper surfaces and lateral surfaces of both side portions of the channel layer 110b. A portion of the source electrode 120b and a portion of the drain electrode 130b may overlap the channel layer 110b in the thickness direction of the channel layer 110b, and the remaining portion of the source electrode 120b and the remaining portion of the drain electrode 130b may not overlap the channel layer 110b. Accordingly, planar and edge contacts may be formed between the source electrode 120b and the drain electrode 130b and both side portions of the channel layer 110b. A planar contact may be formed between the source electrode 120b and the drain electrode 130b and upper surfaces of the both side portions of the channel layer 110b, and an edge contact may be formed between the source electrode 120b and drain electrode 130b and lateral surfaces of the both side portions of the channel layer 110b. -∥ For example, the 2D material layer of the channel layer 110b, and an alloy layer of the source electrode 120b and the drain electrode 130b may form a contact of a vertical and lateral heterojunction structure.

The alloy layers included in the source electrode 120b and the drain electrode 130b may be provided on both sides of the 2D material layer included in the channel layer 110b to be in contact with the both sides of the 2D material layer, so that contact resistance may be reduced.

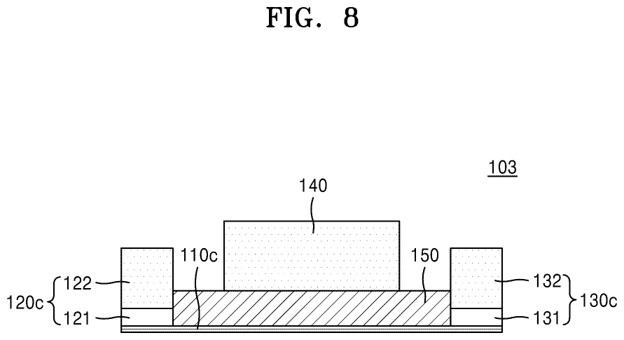

FIG. 8 is a cross-sectional view of a semiconductor device 103 including a metal layer, according to an embodiment. Differences from the embodiments described above are mainly described.

Referring to FIG. 8, a channel layer 110 includes the 2D material layer described above with reference to FIG. 1. The 2D material layer may include, but is not limited to, a material having a band gap of about 0.1 eV to about 3.0 eV. The 2D material layer may include, for example, TMD, black phosphorus, or graphene. However, this is only an example. TMD may include, for example, a transition metal including at least one of Mo, W, Nb, Sn, V, Ta, Ti, Zr, Hf, Tc, and Re, and a chalcogen element including at least one of S, Se, and Te.

The 2D material layer included in the channel layer 110c may have a single-layer or multi-layer structure. For example, the 2D material layer may include, but is not limited to, 1 to 10 layers (e.g., 1 to 5 layers). The channel layer 110c may further include a desired and/or alternatively predetermined dopant, such as a p-type dopant or an n-type dopant.

The gate insulating layer 150 is provided at the center of the channel layer 110c, and the gate electrode 140 is provided on the gate insulating layer 150. The gate insulating layer 150 may include, for example, a silicon nitride, but embodiments are not limited thereto. The gate electrode 140 may include a metal, a conductive nitride, or a conductive oxide.

A source electrode 120c and a drain electrode 130c are provided on both sides of the channel layer 110c including the 2D material layer, respectively. The source electrode 120c and the drain electrode 130c may include the alloy layer described above with reference to FIG. 1.

The source electrode 120c and the drain electrode 130c may be provided to contact both side portions of the channel layer 110c. FIG. 8 illustrates a case where the source electrode 120c and the drain electrode 130c form a planar contact by contacting upper surfaces of the both side portions of the channel layer 110c. However, this is only an example, and the source electrode 120c and the drain electrode 130c may form an edge contact by contacting lateral surfaces of the both side portions of the channel layer 110c, and may form planar and edge contacts by contacting the upper surfaces and the lateral surfaces of the both side portions of the channel layer 110c.

The source electrode 120c and the drain electrode 130c may further include metal layers 122 and 132, respectively. For example, the source electrode 120c and the drain electrode 130c may include alloy layers 121 and 131 both in contact with the channel layer 110c, respectively, and the metal layers 122 and 132 disposed on the alloy layers 121 and 131, respectively. The metal layers 122 and 132 may include, for example, a metal material having excellent electrical conductivity, such as Ag, Au, Pt, or Cu, but embodiments are not limited thereto.

The alloy layers 121 and 131 of the source electrode 120c and the drain electrode 130c are provided on the 2D material layer of the channel layer 110c to be in contact with the 2D material layer of the channel layer 110c, so that contact resistance between the channel layer 110a and the source electrode 120c and between the channel layer 110c and the drain electrode 130c may be reduced.

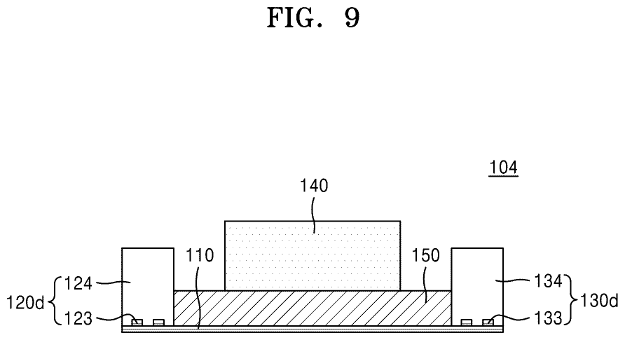

FIG. 9 is a cross-sectional view of a semiconductor device 104 including a plurality of islands, according to an embodiment. Differences from the embodiments described above are mainly described.

Referring to FIG. 9, the semiconductor device 104 includes the channel layer 110 including the 2D material layer of FIG. 1. The 2D material layer may include, for example, TMD, black phosphorus, or graphene. However, this is only an example. The 2D material layer constituting the channel layer 110 may have a single-layer or multi-layer structure. For example, the 2D material layer may include 1 to 10 layers (e.g., 1 to 5 layers). However, embodiments are not limited thereto. The channel layer 110 may further include a desired and/or alternatively predetermined dopant. The gate insulating layer 150 is provided at the center of the channel layer 110, and the gate electrode 140 is provided on the gate insulating layer 150.

A source electrode 120d and a drain electrode 130d are provided on both sides of the channel layer 110 including the 2D material layer, respectively. The source electrode 120d and the drain electrode 130d may include alloy layers 124 and 134, respectively. The alloy layers 124 and 134 may be the alloy layers 12 described above with reference to FIG. 1. The source electrode 120d and the drain electrode 130d may be provided to contact both side portions of the channel layer 110.

A plurality of islands 123 and 133 spaced apart from each other may be disposed at an interface between the source electrode 120d and the channel layer 110 and at an interface between the drain electrode 130d and the channel layer 110. The plurality of islands 123 and 133 are mixed regions of 2D material layers and alloy layers that are formed while the alloy layers 124 and 134 constituting the source electrode 120d and the drain electrode 130d are being deposited on the 2D material layer.

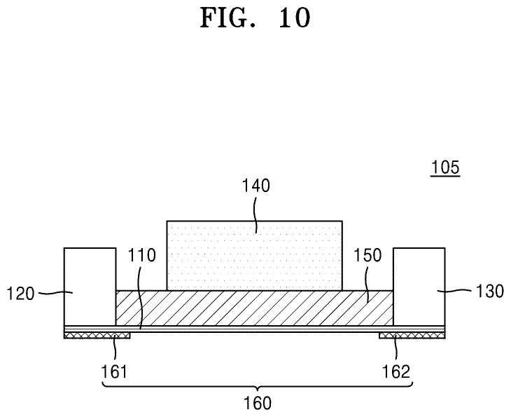

FIG. 10 is a cross-sectional view of a semiconductor device 105 including an alignment adjustment layer, according to an embodiment. Differences from the embodiments described above are mainly described.

A channel layer 110 of the semiconductor device 105 may include the 2D material layer described above with reference to FIG. 1.

The type of 2D material layer having semiconductor characteristics may be changed by energy-band alignment according to contact between the 2D material layer and a source electrode and between the 2D material layer and a drain electrode.

The semiconductor device 105 according to an embodiment may further include an alignment adjustment layer 160 for adjusting energy-band alignment between the channel layer 110 and the source electrode 120 and between the channel layer 110 and the drain electrode 130 in a region other than a region of the channel layer 110 that is in contact with the source electrode 120 and the drain electrode 130.

The alignment adjustment layer 160 may be disposed on a second surface of the channel layer 110 opposite to a first surface of the channel layer 110 on which the source electrode 120 and the drain electrode 130 are disposed. For example, the source electrode 120 and the drain electrode 130 may be disposed on an upper surface of the channel layer 110, and the alignment adjustment layer 160 may be disposed on a lower surface of the channel layer 110. The alignment adjustment layer 160 may include a first alignment adjustment layer 161 overlapping the source electrode 120 in the thickness direction of the channel layer 110, and a second alignment adjustment layer 162 overlapping the drain electrode 130 in the thickness direction of the channel layer 110.

The alignment adjustment layer 160 may provide carriers, e.g., electrons or holes, to the channel layer 110. The electrons or holes may reduce contact resistance between the channel layer 110 and the source electrode 120 and between the channel layer 110 and the drain electrode 130. The electrons or holes provided by the alignment adjustment layer 160 may adjust energy-band alignment between the channel layer 110 and the source electrode 120 and between the channel layer 110 and the drain electrode 130.

The alignment adjustment layer 160 may include an insulative 2D material. Because the alignment adjustment layer 160 is made of a 2D material, scaling of the thin film structure 10 may be reduced. For example, a thickness of the alignment adjustment layer 160 may be a thickness of the channel layer 110 or less. Because the alignment adjustment layer 160 is composed of a 2D material and is thus stable, diffusion of the material of the alignment adjustment layer 160 into the 2D material layer 11 having semiconductor characteristics may be prevented.

The first alignment adjustment layer 161 may be formed of a material capable of providing holes to the channel layer 110. For example, a work function of the first alignment adjustment layer 161 may be higher than an ionization energy of the channel layer 110. The first alignment adjustment layer 161 may include at least one of RuCl₃, NbS₂, MoO₃. Cr₂C₂O₂, V₂CF₂, Y₂CO₂, Hf₃C₂O₂, Y₄C₃O₂, VS₂, Ti₄C₃O₂, Ti₃C₂O₂, Cr₄N₃O₂, V₃C₂O₂, Mn₂NO₂, V₄C₃O₂, Mn₄N₃O₂, and V₂CO₂. Because the first alignment adjustment layer 161 provides holes to the channel layer 110, energy-band alignment between the channel layer 110 and the source electrode 120 may be adjusted in a positive direction, so that a region of the channel layer 110 adjacent to the source electrode 120 may be p-type.

The second alignment adjustment layer 162 may be formed of a material capable of providing electrons to the channel layer 110. For example, a work function of the second alignment adjustment layer 162 may be lower than electron affinity of the channel layer 110. The second alignment adjustment layer 162 may include at least one of WO3, electrides, and Mxenes. The second alignment adjustment layer 162 may include at least one of Ca₂N, Sr₂N, Ba₂N, Y₂C, Gd₂C, Tb₂C, Dy₂C, and Ho₂C, which is an electride-based material. The second alignment adjustment layer 162 may include at least one of Mn₂NO₂H₂, Mn₂CO₂H₂, V₂CO₂H₂, Ti₄C₂O₂H₂, Ti₂CO₂H₂, Ti₂NO₂H₂, Ti₄N₃O₂H₂, Y₄N₃F₂, Hf₃C₂F₂, and Zr₃C₂F₂, which is an MXene-based material. Because the second alignment adjustment layer 162 provides electrons to the channel layer 110, band alignment between the channel layer 110 and the drain electrode 130 may be adjusted in a negative direction, so that a region of the channel layer 110 adjacent to the drain electrode 130 may be n-type.

Although it has been described above that the first alignment adjustment layer 161 and the second alignment adjustment layer 162 overlap the source electrode 120 and the drain electrode 130, respectively, embodiments are not limited thereto. The first alignment adjustment layer 161 and the second alignment adjustment layer 162 may overlap the drain electrode 130 and the source electrode 120, respectively. The semiconductor device 105 may include only one of the first alignment adjustment layer 161 and the second alignment adjustment layer 162. For example, the semiconductor device 100 may include the first alignment adjustment layer 161 providing holes.

The semiconductor devices 100, 101, 102, 103, 104, and 105 described above may be applied to memory devices such as dynamic random access memory (DRAM) devices. The memory device may have a structure in which the semiconductor devices 100, 101, 102, 103, 104, and 105 described above are electrically connected to a capacitor. The semiconductor devices 100, 101, 102, 103, 104, and 105 may be applied to various electronic apparatuses. For example, the aforementioned semiconductor devices 100, 101, 102, 103, 104, and 105 may be used for arithmetic operations, program execution, temporary data retention, etc. in electronic apparatuses, such as mobile devices, computers, laptop computers, sensors, network devices, and neuromorphic devices.

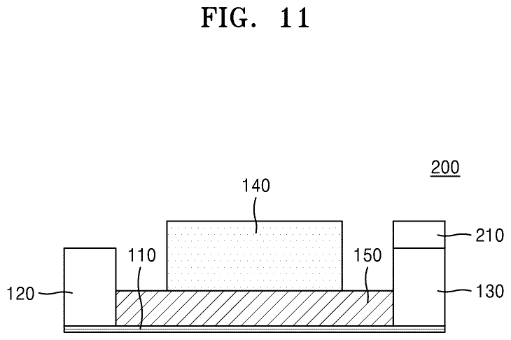

FIG. 11 shows a memory device using the semiconductor device 100 described above as a switching device and including a data storage element connected to the switching device.

Referring to FIG. 11, a semiconductor device 200 includes a data storage element 210 on an interlayer insulating layer. The data storage element 210 may entirely cover the upper surface of the drain electrode 130 and may be in direct contact with the upper surface of the drain electrode 130. The data storage element 210 may include a capacitor, a ferroelectric capacitor, and a magnetic tunnel junction (MTJ) cell. Depending on the data storage element 210, the memory device 200 may be a volatile memory device, such as DRAM, or a non-volatile memory device, such as ferroelectric RAM (FRAM), magnetoresistive RAM (MRAM), and resistive RAM (ReRAM).

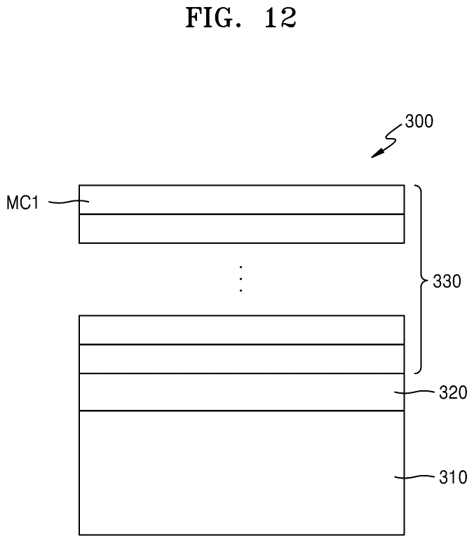

FIG. 12 is a diagram of a memory apparatus in which a plurality of memory devices MC1 as illustrated in FIG. 11 are stacked vertically.

Referring to FIG. 12, a memory logic layer 320 controlling operations of a memory apparatus 300 is on a substrate 310, and a memory cell array 330 is provided on the memory logic layer 320. The memory cell array 330 includes a plurality of memory cells MC1 that are vertically stacked. For example, the memory cell MC1 may be the memory device 200 of FIG. 11.

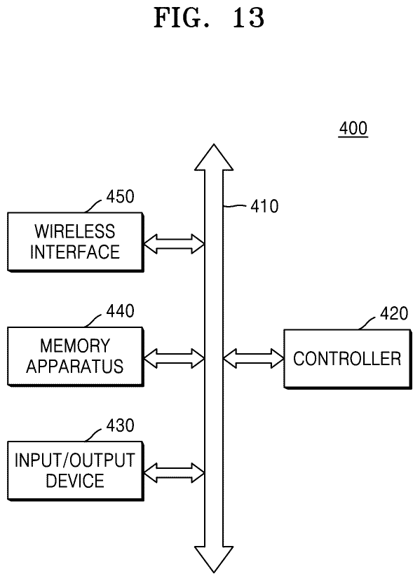

FIG. 13 is a block diagram for schematically explaining an electronic apparatus 400 including a memory apparatus according to an embodiment.

Referring to FIG. 13, the electronic apparatus 400 according to an embodiment may be one of a personal digital assistant (PDA), a laptop computer, a portable computer, a web tablet, a wireless phone, a mobile phone, a digital music player, a wired/wireless electronic appliance, and a combined electronic apparatus including at least two thereof. The electronic apparatus 400 may include a controller 420, an input/output device 430 (such as, a keypad, a keyboard, and a display), a memory apparatus 440, and a wireless interface 450 coupled to one another via a bus 410.

The controller 420 may include, for example, one or more microprocessors, a digital signal processor, a microcontroller, or equivalents thereof. The memory apparatus 440 may be used, for example, to store instructions executed by the controller 420.

The memory apparatus 440 may be used to store user data. The memory apparatus 440 may include the 2D material layer 11 according to an embodiment and the alloy layer 12.

The electronic apparatus 400 may use the wireless interface 450 in order to transmit/receive data to/from a wireless communication network that communicates via RF signals. For example, the wireless interface 450 may include an antenna, a wireless transceiver, etc. The electronic apparatus 400 may be used in a communication interface protocol, such as third-generation communication systems, e.g., code division multiple access (CDMA), global system for mobile communications (GSM), North American digital communications (NADC), extended time division multiple access (E-TDMA), wideband CDMA (WCDMA), and CDMA2000.

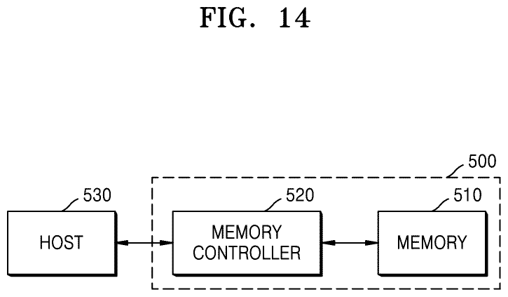

FIG. 14 is a block diagram schematically showing a memory system 500 including a volatile memory apparatus according to an embodiment.

Referring to FIG. 14, volatile memory apparatuses according to an embodiment may be used to implement a memory system. The memory system 500 may include a memory 510 for storing large-capacity data, and a memory controller 520. The memory controller 520 controls the memory 510 to read or write data from or to the memory 510 in response to a read/write request from a host 530. The memory controller 520 may include an address-mapping table for mapping a logical address provided from the host 530, for example, a mobile device or a computer system, to a physical address of the memory 510. The memory 510 may include a 2D material layer according to an embodiment, and an alloy layer.

The memory apparatus according to the embodiment described above may be implemented in the form of a chip and may be used as a neuromorphic computing platform.

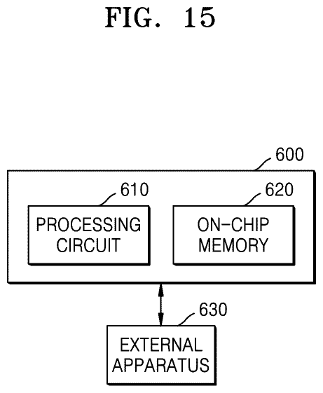

FIG. 15 is a schematic diagram of a neuromorphic apparatus 600 including a memory apparatus according to an embodiment. Referring to FIG. 15, the neuromorphic apparatus 600 may include a processing circuit 610 and an on-chip memory 620.

The processing circuit 610 may be configured to control functions for driving the neuromorphic apparatus 600. For example, the processing circuit 610 may execute programs stored in the on-chip memory 620 of the neuromorphic apparatus 600 to control the neuromorphic apparatus 600. The on-chip memory 620 may include a 2D material layer according to an embodiment, and an alloy layer.

The processing circuit 610 may include hardware, such as a logic circuit, a combination of hardware, such as a processor executing software and software, or a combination thereof. For example, the processor may include a central processing unit (CPU), a graphics processing unit (GPU), an application processor (AP) in the neuromorphic apparatus 600, an arithmetic logic unit (ALU), a digital processor, a microcomputer, a field programmable gate array (FPGA), a system-on-chip (SoC), a programmable logic unit, a microprocessor, an application-specific integrated circuit (ASIC), etc.

The processing circuit 610 may read and write a variety of data from and to an external apparatus 630 and execute the neuromorphic apparatus 600 by using the data. The external apparatus 630 may include a sensor array including an external memory and/or an image sensor (e.g., a CMOS image sensor circuit).

The neuromorphic apparatus 600 illustrated in FIG. 15 may be applied to a machine learning system. The machine learning system may utilize various processing models and various artificial neural network organizations including, for example, a convolutional neural network (CNN), a deconvolutional neural network, a recurrent neural network (RNN) selectively including a long short-term memory (LSTM) and/or a gated recurrent unit (GRU), a stacked neural network (SNN), a state-space dynamic neural network (SSDNN), a deep belief network (DBN), generative adversarial networks (GANs), and/or restricted Boltzmann machines (RBMs).

The machine learning system may include, for example, linear regression and/or logistic regression, statistical clustering, Bayesian classification, decision trees, dimensionality reduction, such as principal component analysis, and another type of machine learning model, such as an expert system, and/or a combination thereof including an ensemble technique, such as random forest. The machine learning model may be used to provide various services, for example, an image classification service, a user authentication service based on biometric information or biometric data, an advanced driver assistance system (ADAS), a voice assistant service, and an automatic speech recognition (ASR) service, and may be installed in other electronic apparatuses to be executed.

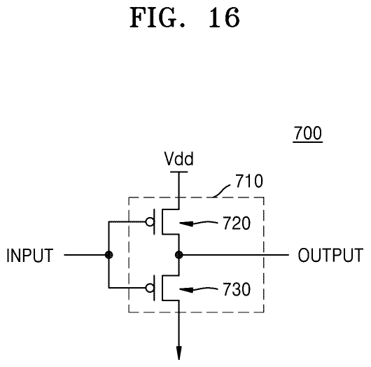

FIG. 16 is a circuit diagram of an inverter according to an embodiment.

The inverter 700 may include a complementary transistor pair 710. The complementary transistor pair 710 includes a PMOS transistor 720 and an NMOS transistor 730 connected between a power terminal Vdd and a ground terminal. The PMOS transistor 720 and NMOS transistor 730 each independently may be implemented using transistors based on one or more of the aforementioned semiconductor devices 100, 101, 102, 103, 104, and 105. The inverter 700 may be used in the aforementioned electronic apparatus 400 and memory system 500, such as in the controller 420 and memory controller 520.

According to an embodiment, contact resistance between a 2D material layer having semiconductor characteristics and an electrode may be reduced by disposing an alloy layer having semimetal characteristics as an electrode on the 2D material layer.

The contact resistance between the 2D material layer having semiconductor characteristics and the electrode may be lowered by disposing an alignment adjustment layer capable of adjusting energy-band alignment on a region of the 2D material layer where no electrodes are disposed.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The aforementioned thin film structures, the aforementioned semiconductor devices including the same, and the aforementioned electronic apparatuses are only examples, and it will be understood by those of ordinary skill in the art that various modifications and other equivalent embodiments may be made therein. It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a two-dimensional material (2D) layer with semiconductor characteristics; and
a source electrode, a drain electrode, and a gate electrode spaced apart from one another on the 2D material layer,
wherein at least one of the source electrode and the drain electrode is in contact with the 2D material layer and comprises an alloy layer that is amorphous.

2. The semiconductor device of claim 1, wherein the alloy layer has semimetal characteristics.

3. The semiconductor device of claim 1, wherein the alloy layer comprises a first metal and a second metal that are different from each other.

4. The semiconductor device of claim 3, wherein the first metal is one of aluminum (Al), gallium (Ga), indium (In), titanium (Ti), and tin (Sn).

5. The semiconductor device of claim 3, wherein the second metal is one of samarium (Sm), europium (Eu), lanthanum (La), cerium (Ce), and lutetium (Lu).

6. The semiconductor device of claim 3, wherein a content of the first metal in the alloy layer is greater than a content of the second metal in the alloy layer.

7. The semiconductor device of claim 3, wherein a ratio of a content of the first metal to a content of the second metal is 8 to 10.

8. The semiconductor device of claim 1, wherein the alloy layer further comprises a chalcogen element.

9. The semiconductor device of claim 8, wherein the chalcogen element comprises at least one of selenium (Se), tellurium (Te), polonium (Po), and livermorium (Lv).

10. The semiconductor device of claim 8, wherein a content of the chalcogen element in the alloy layer is 50 at % or less.

11. The semiconductor device of claim 8, wherein a content of the chalcogen element in the alloy layer is 20 at % or less.

12. The semiconductor device of claim 1, wherein a melting point of the alloy layer is 800° C. or more.

13. The semiconductor device of claim 1, wherein the 2D material layer comprises transition metal dichalcogenide (TMD).

14. The semiconductor device of claim 13, wherein
the TMD comprises a metal element and a chalcogen element,
the metal element includes one of Mo, W, Nb, V, Ta, Ti, Zr, Hf, Tc, Re, Cu, Ga, In, Sn, Ge, and Pb, and
the chalcogen element includes one of S, Se, and Te.

15. The semiconductor device of claim 1, wherein a thickness of the 2D material layer is about 5 nm or less.

16. The semiconductor device of claim 1, wherein at least one of the source electrode and the drain electrode further comprises a metal layer on the alloy layer.

17. The semiconductor device of claim 1, wherein at least one of the source electrode and the drain electrode further comprises a plurality of islands spaced apart from one another between the 2D material layer and the alloy layer.

18. The semiconductor device of claim 1, further comprising:
an alignment adjustment layer on a different region of the 2D material layer than a region of the 2D material layer in which the source electrode and the drain electrode are disposed, wherein
the alignment adjustment layer is configured to adjust energy-band alignment between the 2D material layer and at least one of the source electrode and the drain electrode.

19. The semiconductor device of claim 18, wherein the alignment adjustment layer overlaps at least one of the source electrode and the drain electrode in a thickness direction of the 2D material layer.

20. The semiconductor device of claim 18, wherein the alignment adjustment layer comprises a 2D material having insulating properties.
